(19) United States
(12) Patent Application Publication
(10) Pub. No.: US 2026/0018535 A1
(43) Pub. Date: Jan. 15, 2026

(54) METHOD OF MANUFACTURING SEMICONDUCTOR ELEMENT

(71) Applicant: SAMSUNG ELECTRONICS CO., LTD., Suwon-si (KR)

(72) Inventors: Wonhong CHOI, Suwon-si (KR); Sunghyup KIM, Suwon-si (KR); Youngjeong KIM, Suwon-si (KR); Woongkee KIM, Suwon-si (KR); Jeongdu KIM, Suwon-si (KR); Hyunil KIM, Suwon-si (KR); Hyunggyun NOH, Suwon-si (KR); Injae LEE, Suwon-si (KR); Jonggeon LEE, Suwon-si (KR); June Hyun HAN, Suwon-si (KR)

(21) Appl. No.: 19/179,598

(22) Filed: Apr. 15, 2025

(30) Foreign Application Priority Data
Jul. 9, 2024 (KR) 10-2024-0090348

(51) Int. Cl. H01L 23/00; B32B 37/12; B32B 41/00; H01L 21/66; H01L 21/683; H01L 21/78; H01L 23/48; H01L 25/00

(52) U.S. Cl. CPC H01L 23/562; B32B 37/12; B32B 41/00; H01L 21/6835; H01L 21/78; H01L 22/12; H01L 25/50; B32B 2457/14; H01L 23/481

(57) ABSTRACT

A method of manufacturing a semiconductor element includes preparing integrated circuit chips, obtaining warpage information of each of the integrated circuit chips, deforming at least a portion of a chip stress control pattern of each of the integrated circuit chips according to the warpage information of each of the integrated circuit chips, laminating the integrated circuit chips on a carrier substrate with adhesive layers interposed therebetween, curing the adhesive layers, and removing chip scribe lane areas from the integrated circuit chips.

### CROSS-REFERENCE TO RELATED APPLICATIONS

This application claims priority under 35 U.S.C. § 119 to Korean Patent Application No. 10-2024-0090348, filed on Jul. 9, 2024 in the Korean Intellectual Property Office, the disclosure of which is incorporated by reference herein in its entirety.

### BACKGROUND

Embodiments of the present disclosure described herein relate to a method of manufacturing a semiconductor element, and more particularly, relate to a method of manufacturing a semiconductor element including integrated circuit chips.

With the rapid development of the electronics industry and the demands of users, electronic devices are becoming smaller and lighter. Accordingly, high integration is required for semiconductor elements used in the electronic devices. The semiconductor element may include, for example, various laminated integrated circuit chips. However, the integrated circuit chips may be warped according to a process condition of manufacturing the integrated circuit chips. This warpage causes deterioration in quality of the semiconductor element that is a final result.

### SUMMARY

Embodiments of the present disclosure provide a semiconductor element in which warpage is prevented or reduced and a method of manufacturing a semiconductor package including the same.

According to some embodiments, a method of manufacturing a semiconductor element includes preparing integrated circuit chips, each of the integrated circuit chips including a chip substrate having a chip area and a chip scribe lane area in which a chip stress control pattern is formed, obtaining warpage information of each of the integrated circuit chips, deforming at least a portion of the chip stress control pattern of each of the integrated circuit chips according to the warpage information of each of the integrated circuit chips, laminating the integrated circuit chips on a carrier substrate with adhesive layers interposed therebetween, curing the adhesive layers, and removing the chip scribe lane areas from the integrated circuit chips.

According to some embodiments, a method of manufacturing a semiconductor element includes preparing a substrate including chip areas and a scribe lane area between the chip areas, forming a stress control pattern on the scribe lane area, preparing integrated circuit chips by cutting the substrate along a cutting line defined on the scribe lane area, each of the integrated circuit chips including one of the chip areas, a chip scribe lane area, and a chip stress control pattern, obtaining warpage information of each of the integrated circuit chips, deforming at least a portion of the chip stress control pattern of each of the integrated circuit chips according to the warpage information of each of the integrated circuit chips, laminating the integrated circuit chips on a carrier substrate with non-conductive adhesive films interposed therebetween, thermally compressing and curing the non-conductive adhesive films, and removing the chip scribe lane areas from the integrated circuit chips.

According to some embodiments, a method of manufacturing a semiconductor package includes manufacturing a semiconductor element and mounting the semiconductor element on a package substrate.

### BRIEF DESCRIPTION OF THE FIGURES

The above and other objects and features of the present disclosure will become apparent by describing in detail embodiments thereof with reference to the accompanying drawings.

FIG. 1A is a cross-sectional view illustrating a semiconductor element according to some embodiments of the present disclosure.

FIG. 1B is a cross-sectional view illustrating the semiconductor element of FIG. 1A in detail.

FIG. 2A is a flowchart sequentially illustrating a method of manufacturing a semiconductor element according to some embodiments of the present disclosure.

FIG. 2B is a flowchart sequentially illustrating an operation of preparing integrated circuit chips in operations disclosed in FIG. 2A.

FIGS. 3A to 3O are cross-sectional views sequentially illustrating the method of manufacturing a semiconductor element according to some embodiments of the present disclosure.

FIG. 4 is a cross-sectional view illustrating an operation of laminating integrated circuit chips on a carrier substrate according to some embodiments of the present disclosure.

FIG. 5 is a cross-sectional view illustrating an operation of laminating the integrated circuit chips on the carrier substrate according to some embodiments of the present disclosure.

FIG. 6A is a cross-sectional view illustrating the semiconductor element according to some embodiments of the present disclosure.

FIG. 6B is a cross-sectional view illustrating the semiconductor element of FIG. 6A in detail.

FIGS. 7A to 7E are cross-sectional views sequentially illustrating the method of manufacturing a semiconductor element illustrated in FIGS. 6A and 6B.

FIGS. 8A to 8C are views illustrating warpage of chip substrates according to an experimental example.

FIG. 9 is a graph illustrating warpage distribution when a chip stress control pattern is selectively deformed according to warpage after the chip stress control pattern is formed.

FIG. 10 illustrates a semiconductor package according to some embodiments of the present disclosure.

FIG. 11 illustrates a semiconductor package according to some embodiments of the present disclosure.

### DETAILED DESCRIPTION

The present disclosure relates to a method of manufacturing a semiconductor element, and for convenience of description, a semiconductor element will be described first, and a method of manufacturing the same will be described later. Hereinafter, embodiments of the present disclosure will be described in detail with reference to the accompanying drawings.

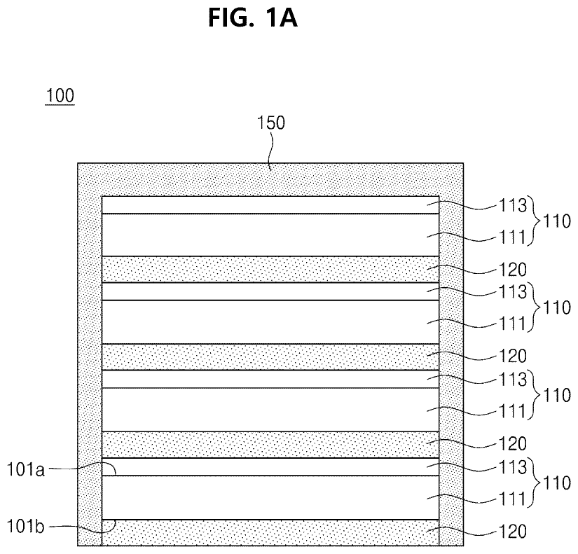

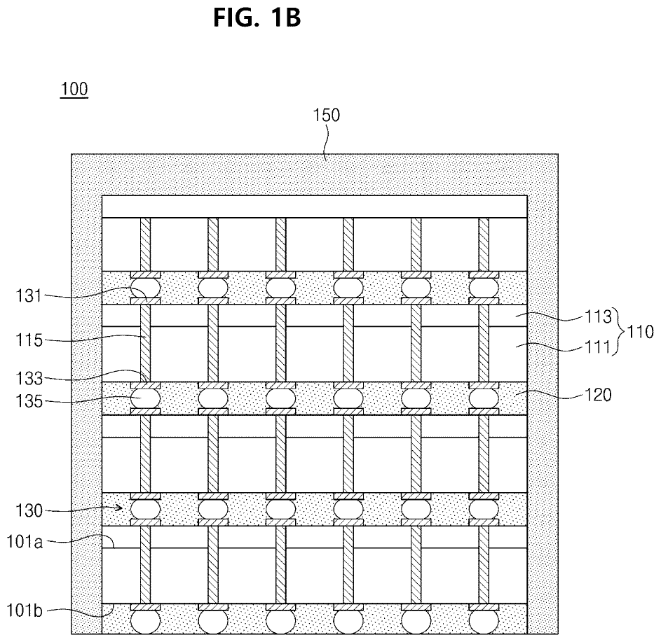

FIG. 1A is a cross-sectional view illustrating a semiconductor element according to some embodiments of the present disclosure, and FIG. 1B is a cross-sectional view illustrating the semiconductor element of FIG. 1A in detail.

Referring to FIGS. 1A and 1B, a semiconductor element 100 according to some embodiments of the present disclosure may include a plurality of integrated circuit chips 110, for example, four integrated circuit chips 110. The plurality of integrated circuit chips 110 may be sequentially laminated with adhesive layers 120 interposed therebetween.

The integrated circuit chips 110 may be logic chips and/or memory chips. For example, all of the plurality of integrated circuit chips 110 may be the same type memory chips or some of the plurality of integrated circuit chips 110 may be memory chips and the others thereof may be logic chips. For example, the memory chip may be a volatile memory chip such as a dynamic random access memory (DRAM) or a static random access memory (SRAM) or a non-volatile memory chip such as a phase-change random access memory (PRAM), a magneto-resistive random access memory (MRAM), a ferroelectric random access memory (FeRAM), or a resistive random access memory (RRAM). In some embodiments of the present disclosure, the integrated circuit chips 110 may be high bandwidth memory (HBM) DRAMs. Further, the logic chip may be, for example, a microprocessor, an analog element, or a digital signal processor.

Meanwhile, FIG. 1A and FIG. 1B illustrate the semiconductor element 100 in which the four integrated circuit chips 110 are laminated, but the number of integrated circuit chips 110 laminated in the semiconductor element 100 is not limited thereto. For example, two, three, or five or more integrated circuit chips 110 may be laminated in the semiconductor element 100.

Each of the integrated circuit chips 110 may include a chip substrate 111 and a circuit layer 113 provided on the chip substrate 111.

The chip substrate 111 may include a front or upper surface 101a and a rear or lower surface 101b. The front surface 101a and the rear surface 101b are surfaces facing each other, the front surface 101a may be a surface on which the circuit layer 113 is formed among both surfaces of the chip substrate 111, and the rear surface 101b may be a surface opposite to the front surface 101a. The front surface 101a may be an active surface on which a plurality of integrated circuits are formed, and the rear surface 101b may be an inactive surface.

The chip substrate 111 may be, for example, a doped or undoped silicon (Si) substrate. In other embodiments, the chip substrate 111 may include other semiconductor materials such as germanium, compound semiconductors including a silicon carbide, gallium arsenic, gallium phosphide, indium phosphide, indium arsenic compound and/or indium antimony compound, hybrid semiconductors including SiGe, GaAsP, AlInAs, GaInAs, GaInP and/or GaInAsP, or a combination thereof. The chip substrate 111 may be formed in a single layer or a plurality of layers. In some embodiments, the chip substrate 111 may have a silicon-on-insulator (SOI) structure. For example, the chip substrate 111 may include a buried oxide (BOX) layer. The chip substrate 111 may include a conductive area, for example, an impurity-doped well or an impurity-doped structure. Further, the chip substrate 111 may have various element isolation structures such as a shallow trench isolation (STI) structure.

The circuit layer 113 may be provided on the front surface 101a of the chip substrate 111. The circuit layer 113 may include a plurality of individual elements and/or wiring lines connecting the individual elements.

The integrated circuit chips 110 may further include a through via 115, a first pad 131, and a second pad 133. The through via 115 may pass through the chip substrate 111 and extend from the front surface 101a of the chip substrate 111 toward the rear surface 101b or from the rear surface 101b toward the front surface 101a. The through via 115 may be connected to wiring lines provided in the circuit layer 113 or may pass through the circuit layer 113 to be connected to the first pad 131 and/or the second pad 133. The through via 115, the first pad 131, and/or the second pad 133 may be directly connected as illustrated or may be electrically connected through various other wiring lines.

In each of the integrated circuit chips 110, the first pad 131 may be disposed on the circuit layer 113. The first pad 131 may be electrically connected to a wiring line structure inside the circuit layer 113 or may be directly connected to the through via 115. The second pad 133 may be disposed on the rear surface 101b of the chip substrate 111 and electrically connected to the through via 115.

The first pads 131 and/or the second pads 133 may include a metal, a metal nitride, a metal oxide, a metal silicide, a conductive carbon, or a combination thereof. For example, the first and/or second pads 131 and 133 may include Ag, Al, AlN, Au, Be, Bi, Co, Cu, Hf, In, Mn, Mo, Ni, Pb, Pd, Pt, Rh, Re, Ru, Sn, Ta, TaN, Te, Ti, TiN, W, WN, Zn, Zr, or a combination thereof. In some embodiments, the first pads 131 and/or the second pads 133 may include one of Al, Cu, Ni, W, Pt, and Au.

Two adjacent integrated circuit chips 110 may be connected to each other by connectors 135. The connectors 135 may be provided between the first pad 131 and the second pad 133 facing each other between two adjacent integrated circuit chips 110. The connectors 135 connecting the two adjacent integrated circuit chips 110 may be at least one of a conductive bump, a conductive ball, a conductive pin, a conductive lead, a conductive pillar, or a combination thereof. For example, each of the connectors 135 may include an under bump metal (UBM) and a conductive bump.

The first pads 131, the second pads 133, and the connectors 135 may constitute or define connection terminals 130 connecting the two adjacent integrated circuit chips 110. The connection terminals 130 may be provided inside the adhesive layers 120. The adhesive layers 120 may be filled or provided between the two integrated circuit chips 110 in which the connection terminals 130 are provided.

The connectors 135 connected to the rear surface 101b of the lowermost integrated circuit chip 110 may be used to electrically connect the semiconductor element 100 to external components, for example, a base substrate, an interposer, a package substrate, and the like, which will be described below. The connectors 135 connected to the rear surface 101b of the lowermost integrated circuit chip 110 may transmit at least one of a control signal, a power signal, or a ground signal for operating the integrated circuit chips 110 from the outside to the integrated circuit chips 110, receive a data signal to be stored in the integrated circuit chips 110 from the outside, or provide data stored in the integrated circuit chips 110 to the outside.

The first pads 131 may not be provided on the circuit layer 113 of the uppermost integrated circuit chip 110. Because the first pads 131 may not be provided, the through vias 115 connected to the first pads 131 may not be provided.

The adhesive layers 120 may be configured to attach the two adjacent integrated circuit chips 110 and may include a polymer material cured through heat and/or light. For example, the adhesive layers 120 may include a resin and a filler. In some embodiments, the resin may have thermosetting properties, and the filler may include fine particles such as silica, but the present disclosure is not limited thereto. In some embodiments, the adhesive layers 120 may be non-conductive films (NCFs). Further, the adhesive layers 120 may be die attach films (DAFs).

The semiconductor element 100 may further include an encapsulant 150 surrounding an upper surface of the uppermost integrated circuit chip 110, side surfaces of the integrated circuit chips 110, and side surfaces of the adhesive layers 120. Materials may be used for the encapsulant 150 and may include, for example, an epoxy mold compound (EMC) or the like.

In some embodiments of the present disclosure, the semiconductor element 100 provides a result of minimizing warpage by forming a stress control pattern during a manufacturing process. This will be described together with reference to the accompanying drawings.

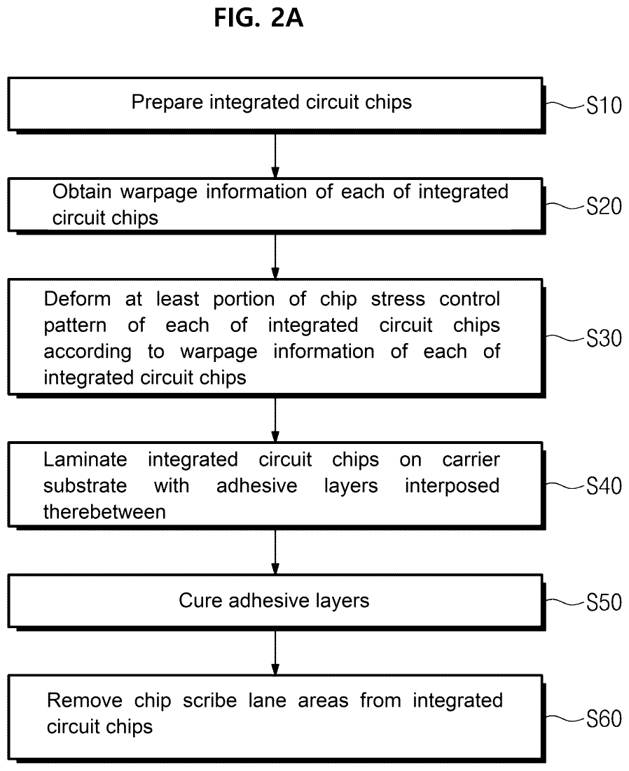

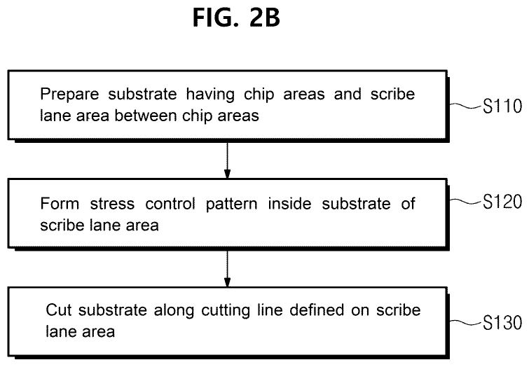

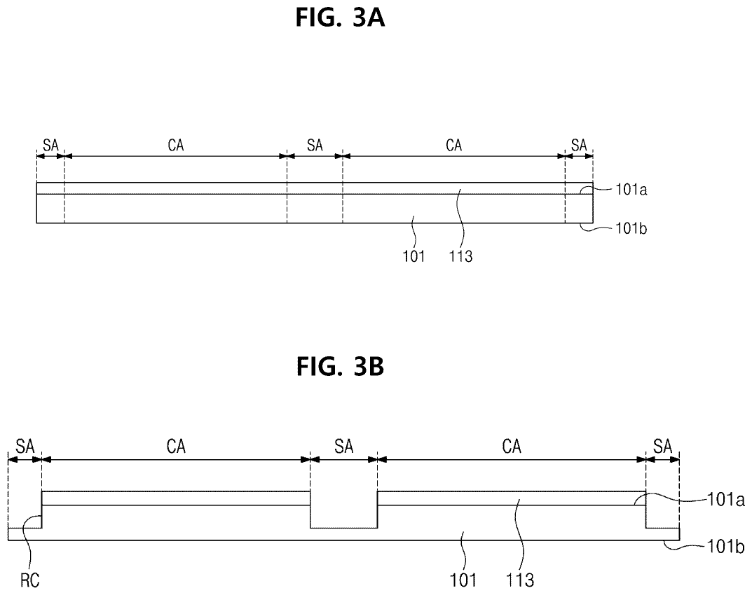

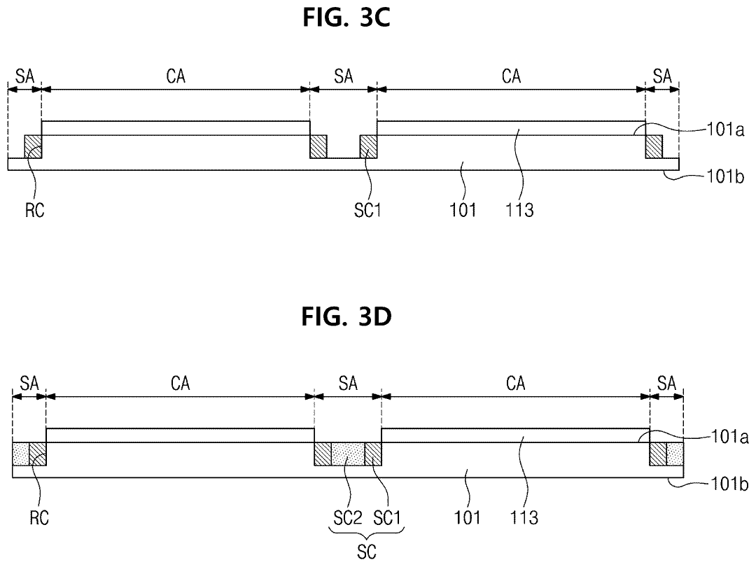

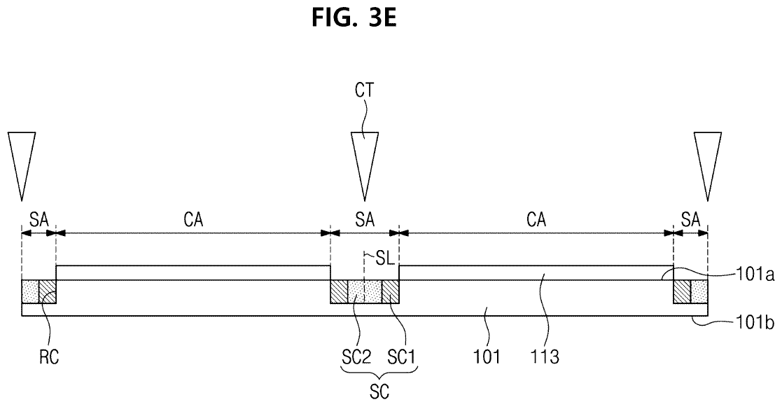

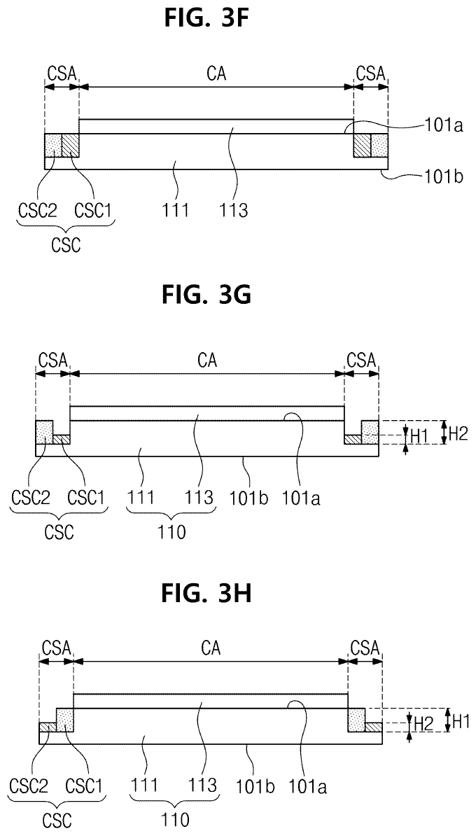

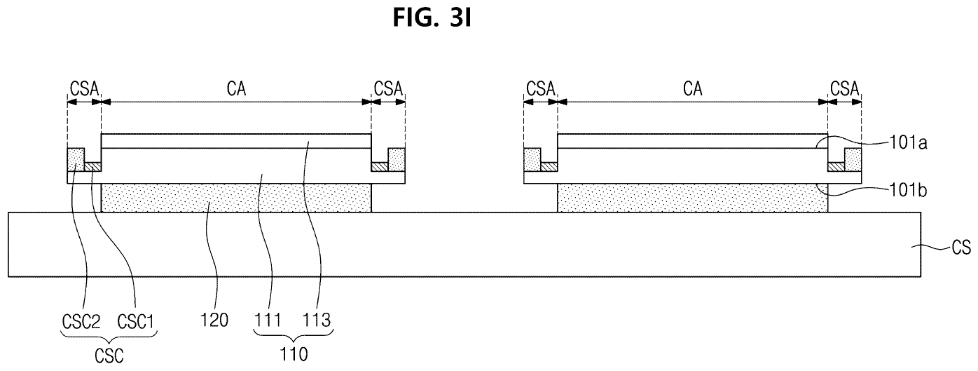

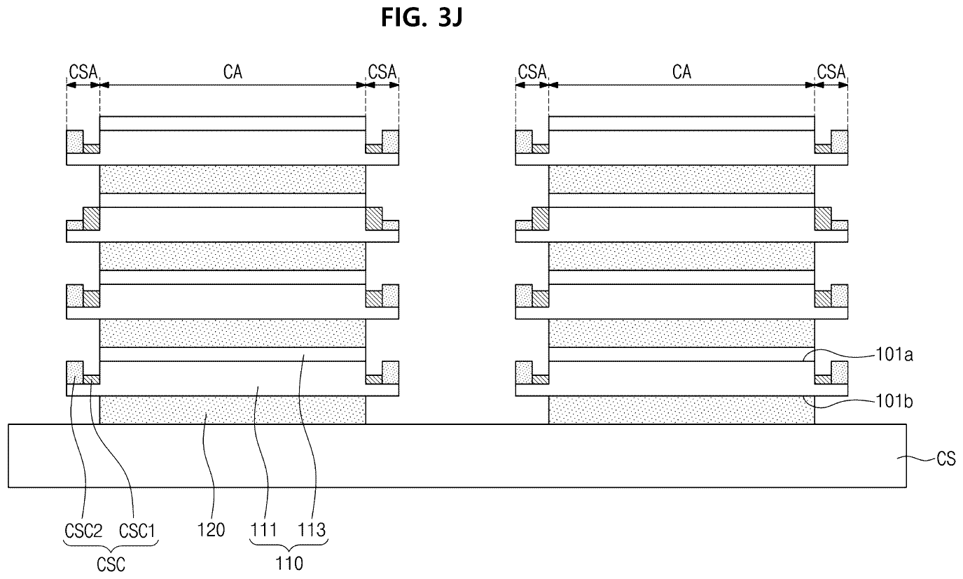

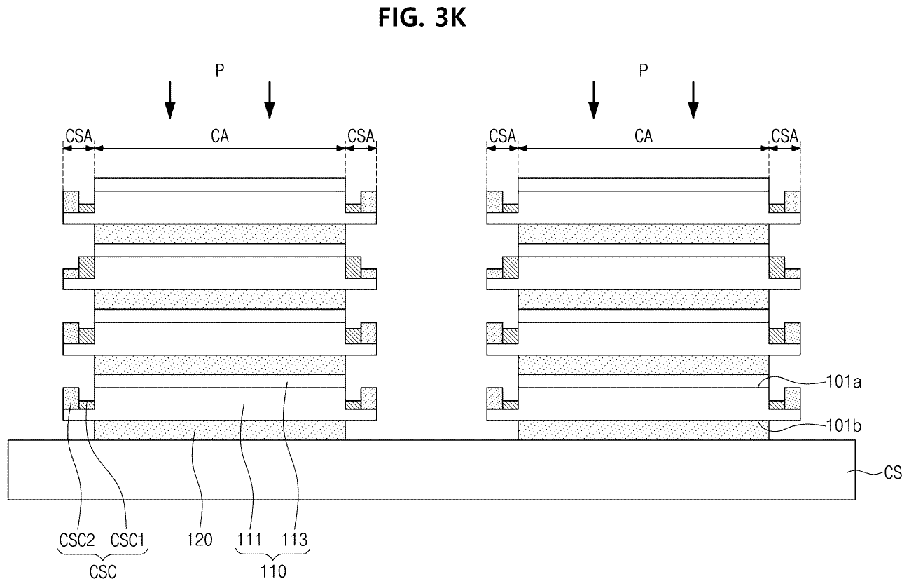

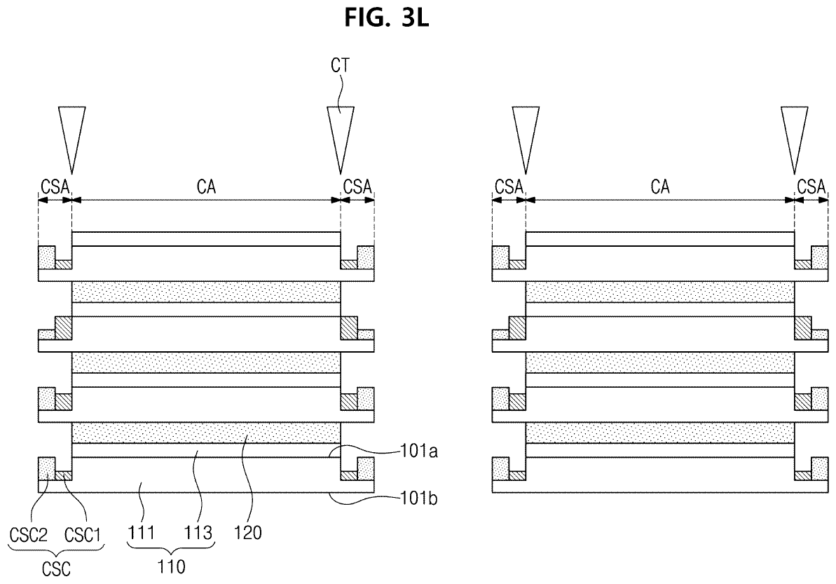

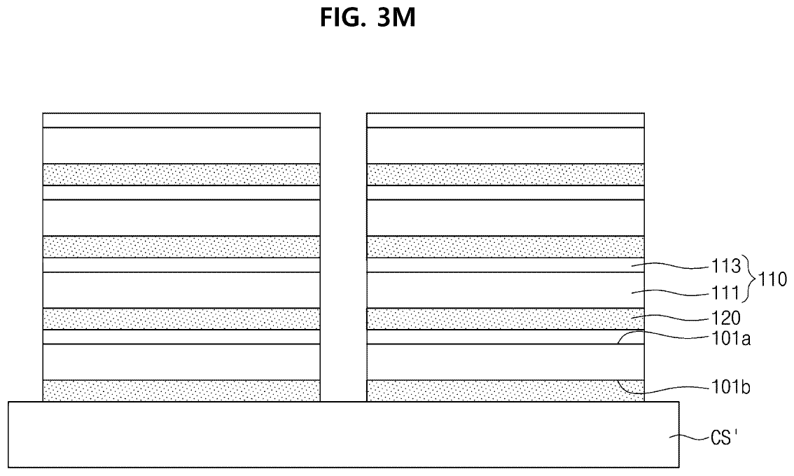

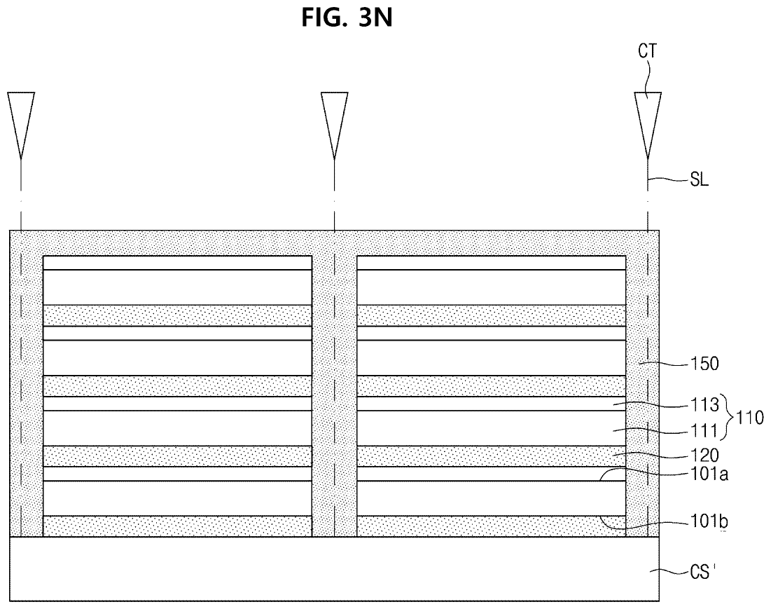

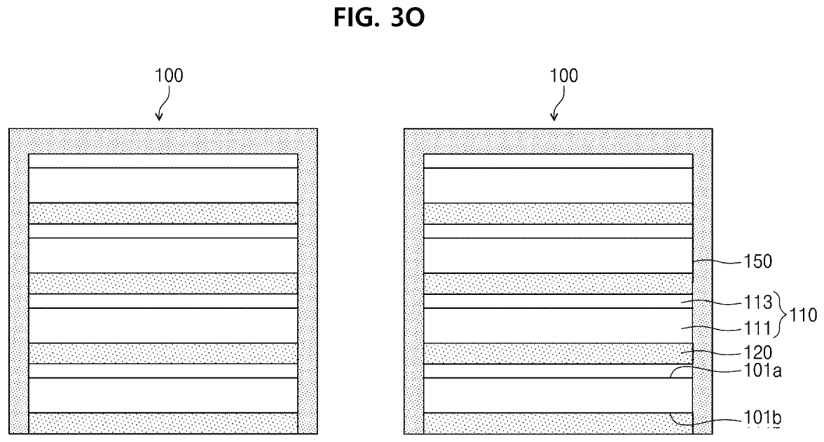

FIG. 2A is a flowchart sequentially illustrating a method of manufacturing a semiconductor element according to some embodiments of the present disclosure, and FIG. 2B is a flowchart sequentially illustrating an operation of preparing integrated circuit chips in operations disclosed in FIG. 2A. FIGS. 3A to 3O are cross-sectional views sequentially illustrating the method of manufacturing a semiconductor element according to some embodiments of the present disclosure.

Referring to FIG. 2A, the semiconductor element according to some embodiments may be manufactured by preparing the integrated circuit chips (S10), obtaining or measuring a warpage degree or warpage information of each of the integrated circuit chips (S20), deforming at least a portion of a chip stress control pattern of each of the integrated circuit chips according to the warpage degree or warpage information of each of the integrated circuit chips (S30), laminating the integrated circuit chips on a carrier substrate with the adhesive layers interposed therebetween (S40), curing the adhesive layers (S50), and removing scribe lane areas from the integrated circuit chips (S60).

The warpage information may mean various pieces of information measured for each warpage. For example, the warpage information may include a warpage direction, a warpage degree, and the like with respect to each of the integrated circuit chips 110.

Referring to FIG. 2B, the integrated circuit chips may be manufactured by preparing a substrate having chip areas and a scribe lane area between the chip areas (S110), forming a stress control pattern inside the substrate of the scribe lane area (S120), and cutting the substrate along a cutting line defined on the scribe lane area (S130).

Hereinafter, the method of manufacturing a semiconductor element according to an order illustrated in FIGS. 2A and 2B will be described in detail with reference to FIGS. 3A to 3O.

Referring to FIG. 3A, a substrate or bulk substrate 101 for forming the integrated circuit chips is prepared. The substrate 101 may include chip areas CA and a scribe lane area SA between the chip areas CA.

The scribe lane area SA may surround four side surfaces of the chip area CA when viewed on a plane (e.g., when viewed from above). Widths of the scribe lane areas SA corresponding to the four side surfaces of the chip area CA may be the same or different from each other.

The chip area CA may include the circuit layer 113 including a plurality of integrated circuits and/or a plurality of wiring lines. The scribe lane area SA may be disposed outside the chip area CA to surround the chip area CA.

Referring to FIG. 3B, a recessed portion RC may be formed in the scribe lane area SA. The recessed portion RC may pass through the circuit layer 113 and may be formed on the front surface 101a of the substrate 101. The recessed portion RC may have a predetermined depth from the front surface 101a of the substrate 101.

Referring to FIGS. 3C and 3D, a stress control pattern SC is formed inside the recessed portion RC. The stress control pattern SC is configured to control a tensile stress and a compressive stress applied to the substrate 101 and the chip substrate 111, which will be described below, and includes a tensile stress pattern SC1 and/or a compressive stress pattern SC2. In the following description, a case in which the stress control pattern SC includes both the tensile stress pattern SC1 and/or the compressive stress pattern SC2 will be described as an example.

Referring back to FIG. 3C, one of the tensile stress pattern SC1 and the compressive stress pattern SC2 may be formed in one area of the recessed portion RC. For example, the tensile stress pattern SC1 may be formed in one area of the recessed portion RC.

The tensile stress pattern SC1 may include a material different from that of the substrate 101. In detail, the tensile stress pattern SC1 may include a first material having a thermal expansion coefficient lower than that of the substrate 101. For example, when the substrate 101 is a silicon substrate, the first material may be a silicon oxide, but the present disclosure is not limited thereto.

The tensile stress pattern SC1 may have the thermal expansion coefficient lower than that of the substrate 101, such that a tensile stress may be generated. The tensile stress pattern SC1 may compensate for a compressive stress generated in the substrate 101 near the tensile stress pattern SC1.

The tensile stress pattern SC1 may be formed by a method of forming a first material layer on the front surface 101a of the substrate 101 using deposition or joining with a first material and removing a portion of the first material layer. For example, the tensile stress pattern SC1 may be formed by a method of forming the first material layer covering a bottom surface and an inner side surface of the recessed portion RC with a predetermined thickness and removing the first material layer covering the bottom surface of the recessed portion RC.

Referring to FIG. 3D, the compressive stress pattern SC2 may be formed inside another area of the recessed portion RC, that is, the recessed portion RC other than an area in which the tensile stress pattern SC1 is formed.

The compressive stress pattern SC2 may include a material different from that of the substrate 101 and the first material. In detail, the compressive stress pattern SC2 may include a second material having a thermal expansion coefficient higher than that of the substrate 101. For example, when the substrate 101 is a silicon substrate, the second material may be polysilicon, but the present disclosure is not limited thereto.

The compressive stress pattern SC2 may have a higher thermal expansion coefficient than that of the substrate 101, and thus a compressive stress may be generated. The compressive stress pattern SC2 may compensate for a compressive stress generated in the substrate 101 near the compressive stress pattern SC2.

The compressive stress pattern SC2 may be formed by a method of forming a second material layer on the front surface 101a of the substrate 101 using deposition or joining with the second material and removing a portion of the second material layer. The compressive stress pattern SC2 may be formed by a method of forming the second material layer covering an inside of the recessed portion RC in which the tensile stress pattern SC1 is formed and removing a portion of the second material layer so that an upper surface of the tensile stress pattern SC1 is exposed.

The method of forming the tensile stress pattern SC1 and the compressive stress pattern SC2 is not limited thereto. Further, a formation order of the tensile stress pattern SC1 and the compressive stress pattern SC2 and/or locations of the tensile stress pattern SC1 and the compressive stress pattern SC2 may be changed within the limitation of the concept of the present disclosure. For example, in the above-described embodiments, when viewed on a cross section, the tensile stress pattern SC1 may be disposed on both sides of the compressive stress pattern SC2, but in some embodiments, the compressive stress pattern SC2 may be also disposed on both sides of the tensile stress pattern SC1. In some embodiments of the present disclosure, when viewed on a plane or a cross-section, areas or shapes of the tensile stress pattern SC1 and the compressive stress pattern SC2 may be variously modified. In particular, the degree of warpage may vary according to the type and process condition of the substrate 101, for example, a cutting location, and the areas or the shapes of the tensile stress pattern SC1 and the compressive stress pattern SC2 may be variously modified in consideration of this.

In some embodiments of the present disclosure, the stress control pattern SC may be formed on the front surface 101a of the substrate 101 on which the circuit layer 113 is formed, but the present disclosure is not limited thereto. The stress control pattern SC may be formed on the rear surface 101b as needed or may be formed on both the front surface 101a and the rear surface 101b according to some embodiments.

Referring to FIG. 3E, the substrate 101 and the circuit layer 113 may be cut along a cutting line SL defined on the scribe lane area SA.

The substrate 101 and the circuit layer 113 may be cut along the cutting line SL, and thus the integrated circuit chips 110 including the plurality of chip substrates 111 may be formed. The cutting line SL may be located on the stress control pattern SC, for example, on the compressive stress pattern SC2.

A cutting process of cutting the substrate 101 and the circuit layer 113 along the cutting line SL and separating the cut portions from each other into the integrated circuit chips 110 may be a process using various cutters CT. For example, the cutting process may include a bevel cut process, a laser sawing process, a blade sawing process, or a combination thereof. In some embodiments, the cutting process may be a process of performing cutting through grinding after laser irradiation.

Referring to FIG. 3F, each of the integrated circuit chips 110 formed by cutting the substrate 101 may include the chip area CA in which the circuit layer 113 is formed and chip scribe lane areas CSA (also referred to herein as scribe line areas) located at both ends of the chip area CA. The chip scribe lane area CSA may surround the four side surfaces of the chip area CA when viewed on a plane (e.g., when viewed from above). Widths of the chip scribe lane areas CSA corresponding to the four side surfaces of the chip area CA may be the same or different from each other.

A chip stress control pattern CSC may be provided in the chip scribe lane area CSA. The chip stress control pattern CSC corresponds to a portion of the stress control pattern SC. The chip stress control pattern CSC may be located in the recessed portion RC of the chip scribe lane area CSA. The chip stress control pattern CSC may include a chip compressive stress pattern CSC2 and a chip tensile stress pattern CSC1.

In some embodiments, a width of the compressive stress pattern SC2 formed on the substrate 101 may be about twice a width of the tensile stress pattern SC1. Accordingly, after the compressive stress pattern SC2 is cut by the cutting line SL crossing the compressive stress pattern SC2, the chip compressive stress pattern CSC2 may have a width similar to that of the chip tensile stress pattern CSC1.

Here, a process of forming the integrated circuit chips 110 by forming the circuit layer 113 on the substrate 101 and cutting the substrate 101 and the circuit layer 113 may correspond to a process of applying various stresses to the substrate 101 and the circuit layer 113, and thus the integrated circuit chips 110 after the cutting may be warped in various forms. For example, the integrated circuit chips 110 may be warped in a concave shape with respect to the front surface 101a of the chip substrate 111 or may be warped in a convex shape with respect to the front surface 101a of the chip substrate 111. In particular, when the chip substrate 111 has anisotropic stress in some areas, the chip substrate 111 may be warped in a concave shape or a convex shape.

Meanwhile, the degree of warpage of the chip substrate 111 may vary according to a process condition of forming the circuit layer 113. When the integrated circuit chips 110 are laminated in a warped state and included in the semiconductor element 100, defects such as interfacial peeling, cracks, and misalignment may occur inside the semiconductor element 100 due to a stress between the integrated circuit chips 110. In particular, when the number of laminated integrated circuit chips 110 increases, the stress between the warped integrated circuit chips 110 may also increase, and thus these defects may increase.

In some embodiments of the present disclosure, the defects may be significantly reduced or prevented by performing a process of obtaining warpage information of each of the integrated circuit chips 110 and correcting the warpage using the stress control pattern SC.

In some embodiments of the present disclosure, the warpage information of the individually separated integrated circuit chips 110 is first measured to correct the warpage of each of the integrated circuit chips 110. The warpage information may mean various pieces of information measured for each warpage. For example, the warpage information may include a warped direction or warpage direction, a warped degree or warpage degree, and the like with respect to each of the integrated circuit chips 110.

Referring to FIGS. 3G and 3H, at least a portion of the chip stress control pattern CSC of each of the integrated circuit chips 110 may be deformed based on the warpage information. At least one of the chip compressive stress pattern CSC2 and the chip tensile stress pattern CSC1 may be deformed by etching according to the warpage information.

In some embodiments, to deform at least a portion of the stress control pattern SC, at least one of the tensile stress pattern SC1 and the compressive stress pattern SC2 may be etched so that the tensile stress pattern SC1 and the compressive stress pattern SC2 have different heights or thicknesses from the bottom surface of the recessed portion RC.

For example, when the chip substrate 111 is warped in a concave shape with respect to the front surface 101a of the chip substrate 111, at least a portion of the chip compressive stress pattern CSC2 may be etched while the tensile stress pattern SC1 is maintained, as in FIG. 3H. The chip compressive stress pattern CSC2 may have a height or thickness H2 lower or smaller than a height or thickness H1 of the chip tensile stress pattern CSC1 due to the etching. Since a size of the chip compressive stress pattern CSC2 may be decreased while the tensile stress pattern SC1 is maintained, a tensile stress is generated more predominantly than a compressive stress in the chip scribe lane area CSA in which the chip stress control pattern CSC is formed. The tensile stress caused by the deformed chip stress control pattern CSC may compensate for a compressive stress on an upper surface of the chip substrate 111, and accordingly, flatness of the integrated circuit chip 110 is improved, and the warpage is improved or reduced.

When the chip substrate 111 is warped in a convex shape with respect to the front surface 101a of the chip substrate 111, at least a portion of the chip tensile stress pattern CSC1 may be etched while the compressive stress pattern SC2 is maintained, as in FIG. 3G. The chip tensile stress pattern CSC1 may have the height or thickness H1 lower or smaller than the height or thickness H2 of the chip compressive stress pattern CSC2 due to the etching. Since a size of the chip tensile stress pattern CSC1 is decreased while the compressive stress pattern SC2 is maintained, a compressive stress is generated more predominantly than a tensile stress in the chip scribe lane area CSA in which the chip stress control pattern CSC is formed. The tensile stress caused by the deformed chip stress control pattern CSC may compensate for the compressive stress on the upper surface of the chip substrate 111, and accordingly, the flatness of the integrated circuit chip 110 is improved, and the warpage is improved or reduced.

The etching of the chip tensile stress pattern CSC1 and/or the chip compressive stress pattern CSC2 may be performed through wet etching, dry etching, or a combination of wet etching and dry etching. The chip tensile stress pattern CSC1 and the chip compressive stress pattern CSC2 include different materials and thus may be selectively etched while etching conditions are changed. For example, the first material may be selectively etched using an etchant having a higher etching ratio for the first material than for the second material.

FIGS. 3G and 3H illustrate that only one of the chip tensile stress pattern CSC1 and the chip compressive stress pattern CSC2 is etched, but the present disclosure is not limited thereto, and both the chip tensile stress pattern CSC1 and the chip compressive stress pattern CSC2 may be etched according to the warpage information. However, in this case, the degrees of etching of the chip tensile stress pattern CSC1 and the chip compressive stress pattern CSC2 may be changed.

Further, the amount of etching for each integrated circuit chip 110 may be changed based on the warpage information. For example, when the chip stress control patterns CSC of the plurality of integrated circuit chips 110 are etched, one of the chip tensile stress pattern CSC1 and the chip compressive stress pattern CSC2 may be etched relatively more in the integrated circuit chip 110 that is warped relatively more, and one of the chip tensile stress pattern CSC1 and the chip compressive stress pattern CSC2 may be etched relatively less in the integrated circuit chip 110 that is warped relatively less.

Referring to FIG. 3I, the integrated circuit chips 110 having improved or reduced warpage through deformation of the chip stress control pattern CSC may be laminated on a carrier substrate CS with the adhesive layer 120 interposed therebetween.

After the adhesive layer 120 is first attached to the rear surface 101b of each of the integrated circuit chips 110, the integrated circuit chips 110 may be laminated on the carrier substrate CS while the adhesive layer 120 is attached. When the integrated circuit chips 110 are laminated on the carrier substrate CS, the rear surface 101b of the chip substrate 111 of each of the integrated circuit chips 110 may face an upper surface of the carrier substrate CS.

The adhesive layers 120 may be configured to attach the two adjacent integrated circuit chips 110 and may include the polymer material cured through heat and/or light. For example, the adhesive layers 120 may include a resin and a filler. In some embodiments of the present disclosure, each of the adhesive layers 120 may be a non-conductive adhesive film. When each of the adhesive layers 120 is a non-conductive adhesive film, the non-conductive adhesive film may be attached to the rear surface 101b of each of the integrated circuit chips 110 after a release film attached to one surface of the non-conductive adhesive film is removed. The integrated circuit chip 110 and the non-conductive adhesive film attached to the rear surface 101b may constitute one unit of the integrated circuit chips 110, and a plurality of units of the integrated circuit chips 110 may be laminated and attached. Here, when the unit of the integrated circuit chip 110 is laminated, after a release film attached to the other surface of the non-conductive adhesive film may be removed, the unit of the integrated circuit chip 110 may be laminated.

Referring to FIG. 3J, a plurality of units of the integrated circuit chips 110 may be laminated according to a semiconductor element to be manufactured. When the plurality of integrated circuit chips 110 are laminated, the chip areas CA of the integrated circuit chips 110 may overlap each other when viewed on a plane, and the chip scribe lane areas CSA of the integrated circuit chips 110 may overlap each other (e.g., vertically overlap each other).

When the non-conductive adhesive films as the adhesive layers 120 are attached to the rear surfaces 101b of the integrated circuit chips 110, each of the non-conductive adhesive films may be attached to overlap the chip area CA of the attached integrated circuit chip 110 when viewed on a plane. The non-conductive adhesive film may have substantially the same size as the chip area CA and may cover the entire chip area CA when viewed on a plane. However, the size or shape of the non-conductive adhesive film is not limited thereto. For example, the non-conductive adhesive film may be formed larger than or smaller than the chip area CA.

Referring to FIG. 3K, as the adhesive layers 120 are cured, the integrated circuit chips 110 arranged with the adhesive layers 120 interposed therebetween may adhere to each other.

The adhesive layers 120 may be thermally cured or photo-cured. When the adhesive layers 120 are thermally cured or photo-cured, the integrated circuit chips 110 may be pressed so that the two adjacent integrated circuit chips 110 are connected to each other by the connection terminals 130. For example, as illustrated in FIG. 3K, the integrated circuit chips 110 and the adhesive layers 120 may be pressed with a predetermined pressure “P,” and may be thermally cured or photo-cured while being pressed. Referring also to FIG. 1B, in some embodiments of the present disclosure, the two adjacent integrated circuit chips 110 in the laminated integrated circuit chips 110 may be electrically connected in a form in which the first pad 131, the connector 135, and the second pad 133 are in contact during thermal compression through the thermal compression.

In some embodiments of the present disclosure, the laminated adhesive layers 120 may be simultaneously cured in a single process. That is, in a state in which the integrated circuit chips 110 are laminated with the adhesive layers 120 interposed therebetween, the integrated circuit chips 110 and the adhesive layers 120 may be simultaneously and thermally compressed. In this case, the process may be very simplified as compared to other embodiments in which the units of the integrated circuit chips 110 are attached by the thermal compression whenever the units of the integrated circuit chips 110 are laminated.

Referring to FIG. 3L, the chip scribe lane areas CSA may be removed from the laminated integrated circuit chips 110.

In some embodiments, before the chip scribe lane areas CSA are removed, the carrier substrate CS may be separated and removed from the laminated integrated circuit chips 110.

The chip scribe lane areas CSA may be cut and removed, and thus a laminated structure of the integrated circuit chips 110 including the chip areas CA is formed. A cutting line serving as a reference for removing the chip scribe lane area CSA may be a boundary line between the chip area CA and the chip scribe lane area CSA.

The process of cutting the chip scribe lane areas CSA may be a process using various cutters CT. For example, the cutting process may include a bevel cut process, a laser sawing process, a blade sawing process, or a combination thereof. In some embodiments, the cutting process may be a process of performing cutting through grinding after laser irradiation.

The semiconductor element including the laminated integrated circuit chips 110 may be formed by removing the chip scribe lane areas CSA.

After the chip scribe lane areas CSA are removed, the encapsulant 150 for encapsulating the laminated integrated circuit chips 110 and the adhesive layers 120 may be formed. A process of forming the encapsulant 150 will be described below.

Referring to FIG. 3M, the plurality of laminated integrated circuit chips 110 may be arranged on an additional carrier substrate CS′.

Referring to FIG. 3N, the encapsulant 150 covering the plurality of laminated integrated circuit chips 110 may be formed on the additional carrier substrate CS′. The encapsulant 150 may surround the upper surface of the uppermost integrated circuit chip 110, the side surfaces of the integrated circuit chips 110, and the side surfaces of the adhesive layers 120. The encapsulant 150 may include various materials and may include, for example, an EMC and the like.

The semiconductor element in which the encapsulant 150 is formed may then be cut through the cutter CT along the cutting line SL and may be separated into individual semiconductor elements. A cutting process of cutting the encapsulant 150 along the cutting line SL and separating the semiconductor element into the semiconductor elements may be a process using various cutters CT. For example, the cutting process may include a bevel cut process, a laser sawing process, a blade sawing process, or a combination thereof. In some embodiments, the cutting process may be a process of performing cutting through grinding after laser irradiation.

Although not illustrated, before the semiconductor element in which the encapsulant 150 is formed is cut, the additional carrier substrate CS' may be separated and removed from the semiconductor element in which the encapsulant 150 is formed.

As in FIG. 3O, the plurality of individual semiconductor elements 100 may be manufactured by cutting the semiconductor element 100 in which the encapsulant 150 is formed.

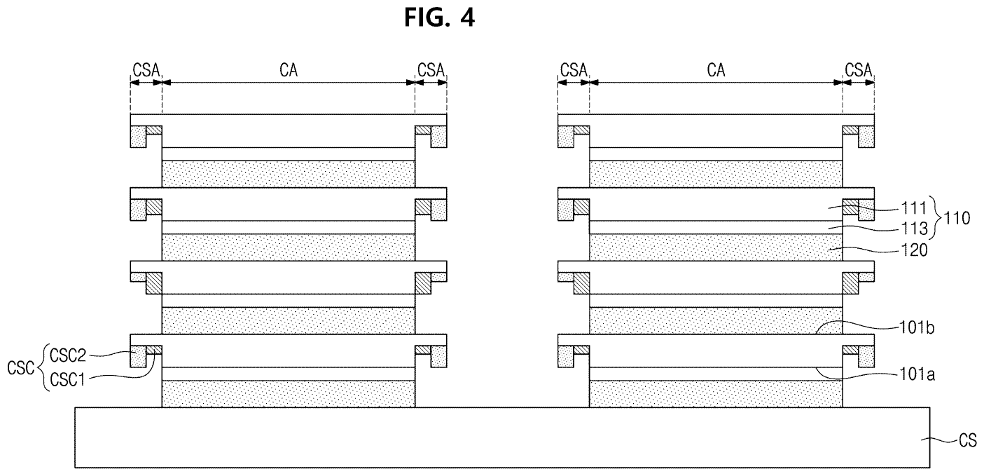

FIG. 4 is a cross-sectional view illustrating an operation of laminating integrated circuit chips on a carrier substrate according to some embodiments of the present disclosure, which corresponds to FIG. 3J.

Referring to FIG. 4, in some embodiments of the present disclosure, the integrated circuit chips 110 may be inverted and laminated when laminated on the carrier substrate CS.

After the adhesive layer 120 is first attached at the front surface 101a of each of the integrated circuit chips 110, that is, on the circuit layer 113, the integrated circuit chips 110 may be laminated on the carrier substrate CS while the adhesive layer 120 is attached. Accordingly, when the integrated circuit chips 110 are laminated on the carrier substrate CS, the front surface 101a of the chip substrate 111 of each of the integrated circuit chips 110 may face the upper surface of the carrier substrate CS.

When the front surfaces 101a of the integrated circuit chips 110 face the carrier substrate CS, the circuit layer 113 of the uppermost integrated circuit chip 110 faces the carrier substrate CS, and thus a through-via may not be formed on the chip substrate 111 of the uppermost integrated circuit chip 110. Further, when the encapsulant 150 is formed, the encapsulant 150 may or may not cover the entire rear surface 101b of the uppermost integrated circuit chip 110. The encapsulant 150 may surround the side surfaces of the integrated circuit chips 110 and the side surfaces of the adhesive layers 120 without covering the upper surface of the uppermost integrated circuit chip 110.

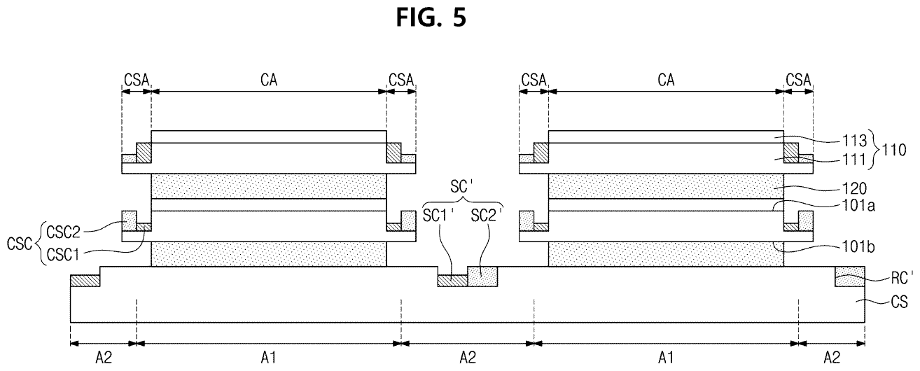

FIG. 5 is a cross-sectional view illustrating an operation of laminating the integrated circuit chips on the carrier substrate according to some embodiments of the present disclosure.

Referring to FIG. 5, the carrier substrate CS may include at least one additional stress control pattern SC for minimizing warpage of the carrier substrate CS.

In more detail, the carrier substrate CS may have a first area A1 in which the integrated circuit chips 110 are laminated and a second area A2 surrounding the first area A1 when viewed on a plane (e.g., when viewed from above). The carrier substrate CS may include the additional stress control pattern SC′ formed in the second area A2. A size of the first area A1 may be the same as a size of the chip areas CA of the integrated circuit chips 110, but the present disclosure is not limited thereto, and the size of the first area A1 may be different from the size of the chip areas CA of the integrated circuit chips 110 as illustrated.

When the carrier substrate CS is warped, it is difficult for the integrated circuit chips 110 to be laminated on the carrier substrate CS, and even when the integrated circuit chips are laminated, defects such as cracks caused by bending may occur in a final semiconductor element. In some embodiments of the present disclosure, the carrier substrate CS may include an additional stress control pattern SC′ that supplements or reduces the warpage of the carrier substrate CS.

The additional stress control pattern SC′ provided to the carrier substrate CS may be provided in a form similar to the chip stress control pattern CSC (see FIG. 3G and FIG. 3H) formed in laminated circuit chips. The carrier substrate CS may have an additional recessed portion RC′ formed in the second area A2, and the additional stress control pattern SC′ may include an additional tensile stress pattern SC1′ provided in one area of the additional recessed portion RC′ and an additional compressive stress pattern SC2′ provided in the other area of the additional recessed portion RC′.

The additional tensile stress pattern SC1′ may include a first material having a thermal expansion coefficient lower than the thermal expansion coefficient of the carrier substrate CS, and the additional compressive stress pattern SC2′ may include a second material having a thermal expansion coefficient higher than the thermal expansion coefficient of the carrier substrate CS. Here, the additional tensile stress pattern SC1′ and the additional compressive stress pattern SC2′ may have different heights or thicknesses from a bottom surface of the additional recessed portion RC′.

A plurality of additional stress control patterns SC′ may be provided on the carrier substrate CS. The plurality of additional stress control patterns SC′ may be provided in the same shape and size or may be provided in different shapes and sizes depending on locations.

As the additional stress control pattern SC′ is provided to the carrier substrate CS, the warpage of the carrier substrate CS may be significantly reduced, and defects of the integrated circuit chips 110 laminated on the carrier substrate CS may be also reduced.

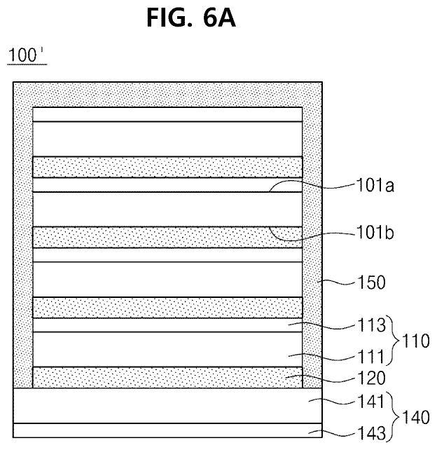

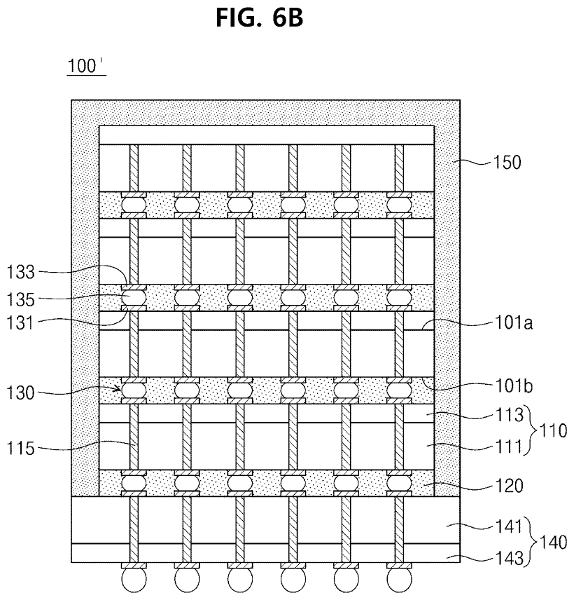

FIGS. 6A and 6B illustrate the semiconductor element according to some embodiments of the present disclosure, FIG. 6A is a cross-sectional view illustrating the semiconductor element according to some embodiments of the present disclosure, and FIG. 6B is a cross-sectional view illustrating the semiconductor element of FIG. 6A in detail.

Referring to FIGS. 6A and 6B, a semiconductor element 100′ according to some embodiments of the present disclosure may include a base chip 140 and the plurality of integrated circuit chips 110. The plurality of integrated circuit chips 110 may include, for example, four integrated circuit chips 110. The base chip 140 and the plurality of integrated circuit chips 110 may be sequentially laminated with the adhesive layers 120 interposed therebetween.

The base chip 140 may include a base chip substrate 141 and a base circuit layer 143 provided on the base chip substrate 141. Each of the integrated circuit chips 110 may include the chip substrate 111 and the circuit layer 113. The base chip 140 and the integrated circuit chips 110 may further include the through via 115, the first pad 131, and the second pad 133.

The base chip 140 and the integrated circuit chips 110 may be logic chips and/or memory chips. For example, all of the plurality of base chips 140 and/or the plurality of integrated circuit chips 110 may be the same type memory chips or some of the plurality of integrated circuit chips 110 may be memory chips and the others thereof may be logic chips. For example, the memory chip may be a volatile memory chip such as a dynamic random-access memory (DRAM) or a static random access memory (SRAM) or a non-volatile memory chip such as a phase-change random access memory (PRAM), a magnetoresistive random access memory (MRAM), a ferroelectric random access memory (FeRAM), or a resistive random access memory (RRAM).

In some embodiments of the present disclosure, the base chip 140 and the integrated circuit chips 110 may be HBM DRAMs. In this case, the base chip 140, which is a buffer chip or a control chip, may integrate signals of a plurality of DRAM chips to transmit the integrated signal to the outside and may also transmit signals and power from the outside to the plurality of DRAM chips. For example, in some embodiments, the base chip 140 may correspond to a master chip. Each of the integrated circuit chips 110 laminated on the base chip 140 may correspond to a slave chip.

The encapsulant 150 surrounding the upper surface of the uppermost integrated circuit chip 110, the side surfaces of the integrated circuit chips 110, and the side surfaces of the adhesive layers 120 may be further included on the base chip 140 and the integrated circuit chips 110. The base chip 140 may have a larger area than the integrated circuit chips 110 when viewed on a plane (e.g., when viewed from above). The base chip 140 may have a larger width than the integrated circuit chips 110. The encapsulant 150 may be provided on the base chip 140 and may not cover a side surface of the base chip 140. An outer surface of the encapsulant 150 and an outer surface of the base chip 140 may form the same plane (e.g., coplanar outer surfaces).

The semiconductor element 100′ illustrated in FIGS. 6A and 6B may be manufactured by preparing the base chip substrate 141, arranging the integrated circuit chips 110, from which the chip scribe lane areas CSA are removed, on the base chip substrate 141, forming the encapsulant 150 for encapsulating the integrated circuit chips 110 arranged on the base chip substrate 141, and cutting the base chip substrate 141 and the encapsulant 150.

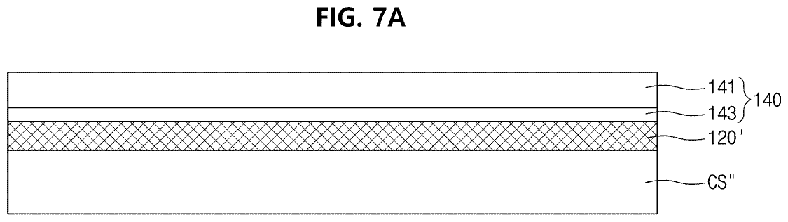

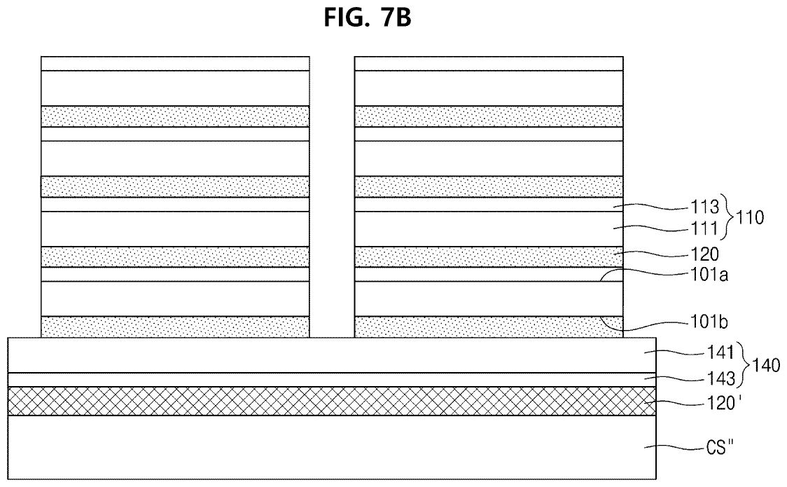

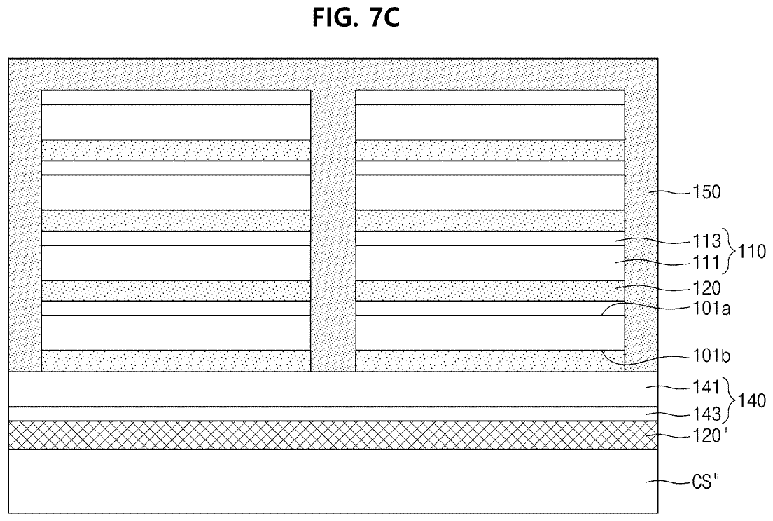

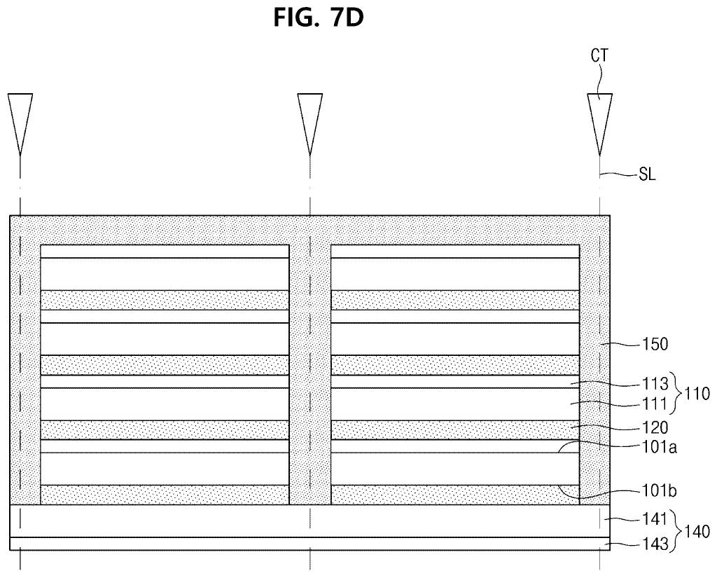

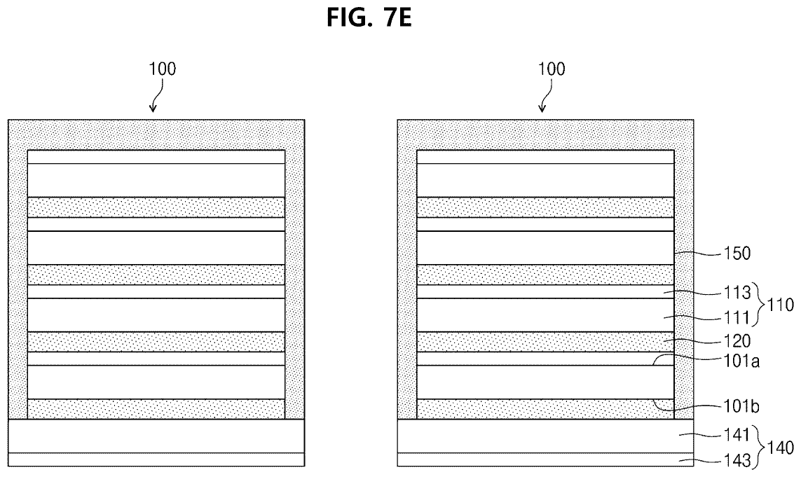

FIGS. 7A to 7E are cross-sectional views sequentially illustrating the method of manufacturing a semiconductor element illustrated in FIGS. 6A and 6B. Hereinafter, differences from the above-described embodiments will be mainly described in the interest of brevity.

Referring to FIG. 7A, the base chip 140 may be prepared. The base chip 140 may adhere to the carrier substrate CS″ with an adhesive layer 120′ interposed therebetween on the separate carrier substrate CS″. The adhesive layer 120′ between the base chip 140 and the carrier substrate CS″ may include the same or similar material as or to the adhesive layer 120 between the integrated circuit chips 110, but the present disclosure is not limited thereto. In some embodiments, the adhesive layer 120′ between the base chip 140 and the carrier substrate CS″ may include a material different from that of the adhesive layer 120 between the integrated circuit chips 110.

Referring to FIG. 7B, the integrated circuit chips 110, from which the chip scribe lane areas CSA are removed, may be arranged on the base chip 140.

Referring to FIG. 7C, the encapsulant 150 for encapsulating the integrated circuit chips 110 arranged on the base chip 140 is formed. The encapsulant 150 may cover the upper surfaces and the side surfaces of the integrated circuit chips 110 and an upper surface of the base chip 140 in an area in which the integrated circuit chips 110 are not provided.

Referring to FIG. 7D, the base chip 140 and the encapsulant 150 may be cut. The base chip 140 and the encapsulant 150 may be cut through the cutter CT along the cutting line SL and may be separated into individual semiconductor elements. The cutting process of cutting the encapsulant 150 along the cutting line SL and separating the semiconductor element into the semiconductor elements may be a process using various cutters CT. For example, the cutting process may include a bevel cut process, a laser sawing process, a blade sawing process, or a combination thereof. In some embodiments, the cutting process may be a process of performing cutting through grinding after laser irradiation.

Although not shown, before the semiconductor elements in which the encapsulant is formed are cut, the carrier substrate may be separated and removed from the semiconductor elements in which the encapsulant is formed.

In the semiconductor elements manufactured through the above-described manufacturing method, defects caused by warpage of the substrate during the manufacturing process are prevented or reduced. This will be described below in more detail.

In the process of manufacturing a semiconductor element, it may be required to laminate the integrated circuit chips as described above. In particular, in an HBM DRAM in which the plurality of integrated circuit chips are laminated, an adhesive force of two adjacent integrated circuit chips is weakened when the integrated circuit chips are laminated in a warped state, and non-uniform stress is applied to the integrated circuit chips, so that the probability of interfacial peeling or cracks occurring in the semiconductor element is increased. Further, when integrated circuit chips are laminated in a warped state, stable laminating in a vertical direction is difficult, and thus misalignment may occur. In particular, the misalignment may be misalignment in the vertical direction in which the integrated circuit chips are laminated. Defects such as interfacial peeling, cracks, and misalignment may cause poor quality and reduced productivity of the semiconductor element.

According to some embodiments of the present disclosure, the warpage of the integrated circuit chips is prevented or reduced, and accordingly, warpage of the entire semiconductor element when the integrated circuit chips are laminated is also prevented or reduced. In addition, flatness of the carrier substrate may be increased by preventing or reducing the warpage of the carrier substrate on which the integrated circuit chips are laminated. When the flatness of the carrier substrate increases, even when the plurality of integrated circuit chips are laminated, an additional warpage preventing effect in the final semiconductor element may be obtained. According to some embodiments of the present disclosure, as a result, various defects in the semiconductor element, such as the interfacial peeling and the cracks in the semiconductor element and the misalignment (especially, the misalignment in the vertical direction) of the integrated circuit chips, are prevented or reduced. Accordingly, when the semiconductor element is manufactured according to some embodiments of the present disclosure, a high-quality semiconductor element may be provided, thereby increasing productivity.

In addition, in some embodiments of the present disclosure, after the plurality of integrated circuit chips are laminated with the adhesive layers interposed therebetween, the connection terminals between the integrated circuit chips are connected in a single process. In particular, when the adhesive layers are non-conductive adhesive films, first pads and second pads provided between two adjacent integrated circuit chips may be connected by connectors (solder balls, microbumps, or the like) through one thermal compression. In this case, as described above, a process may be very simplified as compared to other embodiments in which the adhesive layer is attached by the thermal compression whenever the integrated circuit chip is laminated.

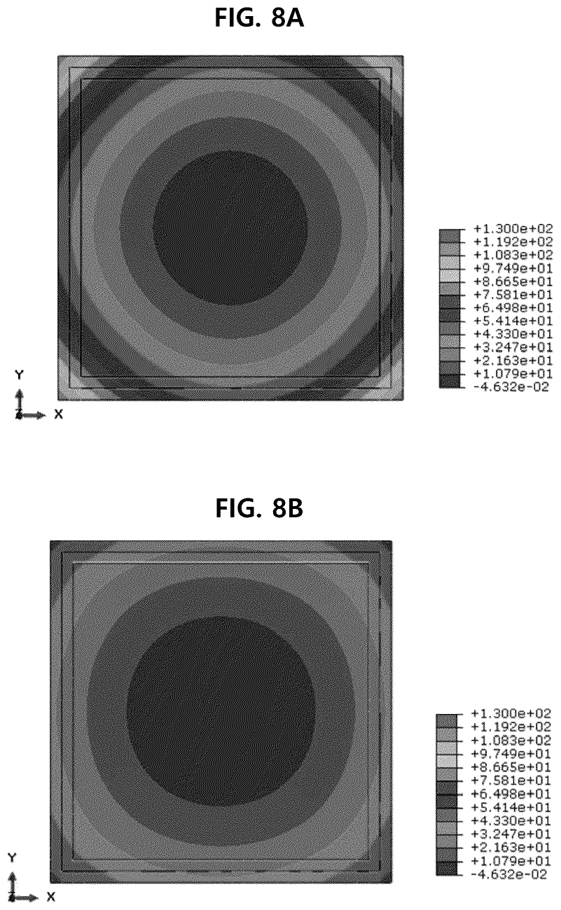

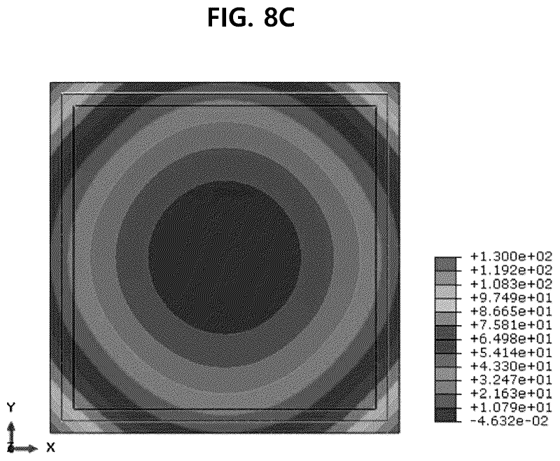

FIGS. 8A to 8C illustrate the warpage of the chip substrates as a result of preparing the chip substrates having the chip area and the scribe lane area and forming the chip stress control pattern in the scribe lane area. In FIGS. 8A to 8C, a conductive adhesive film is attached to the front surface of the chip area of the chip substrate, and a compression stress pattern and a tensile stress pattern are sequentially formed to have the same width from the chip area toward an edge thereof. The chip substrate is heated to 300° C. to induce the warpage and is then cooled at room temperature of 25° C. Each of the chip substrates of FIGS. 8A to 8C is manufactured under the same conditions except for the chip stress control pattern. In the chip stress control pattern, FIG. 8A illustrates that the chip stress control pattern is formed and then maintained without deformation, FIG. 8B illustrates that the tensile stress is induced on the chip substrate by etching the compressive stress pattern in the chip stress control pattern, and FIG. 8C illustrates that the compressive stress is induced in the chip substrate by etching the tensile stress pattern in the chip stress control pattern. The chip substrate is formed of silicon, the tensile stress pattern is formed of a silicon oxide, and the compressive stress pattern is formed of polysilicon. In the present experimental example, the warpage is measured based on a height of the chip substrate farthest from a flat surface when the chip substrate is placed on the flat surface.

Referring to FIG. 8A to FIG. 8C, it may be identified that, when the tensile stress pattern and the compressive stress pattern are provided, and the tensile stress pattern and the compressive stress pattern are deformed according to the warpage, the degree of warpage is significantly changed.

In more detail, when the chip stress control pattern is formed and maintained without deformation as illustrated in FIG. 8A, the chip substrate may be warped. The warpage of the chip substrate increases toward an edge thereof and has the largest value at corners of a quadrangular shape.

However, when the warpage of the chip substrate in FIG. 8A is 100%, the warpage of the chip substrate in FIG. 8B in which the tensile stress is induced is about 49%, and thus a warpage reducing effect of about 51% is achieved. That is, when the tensile stress is generated by etching the compressive stress pattern, the warpage of the chip substrate is significantly reduced. In contrast, in the case of the chip substrate of FIG. 8C in which the compressive stress is induced, the warpage is about 111%, and thus a warpage increasing effect of about 11% is achieved.

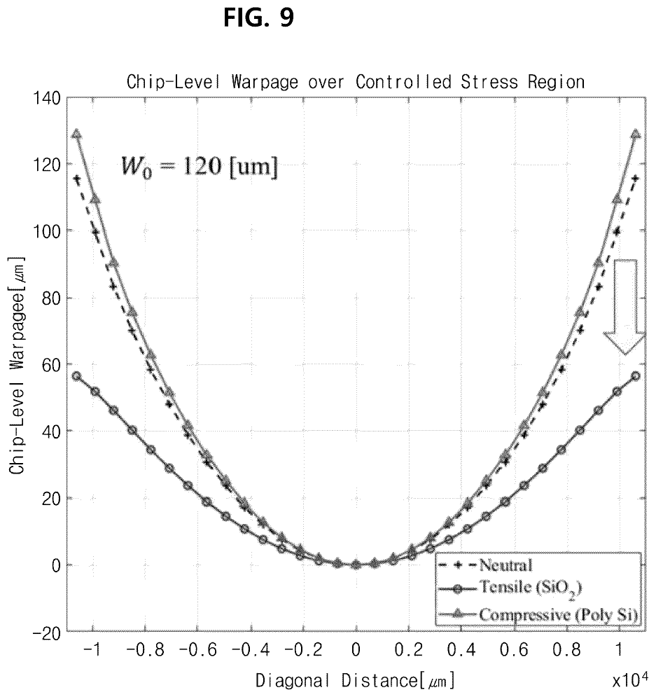

FIG. 9 is a graph illustrating warpage distribution when a chip stress control pattern is selectively deformed according to warpage after the chip stress control pattern is formed. In FIG. 9, a portion represented as a neutral state means an experimental condition of FIG. 8A, a portion represented as a tensile state means an experimental condition of FIG. 8B, and a portion represented as a compressive state means an experimental condition of FIG. 8C.

Referring to FIG. 9, the tendency of the warpage to increase from a center to the edge of the chip substrate is the same regardless of the experimental examples. However, in the case of the chip substrate of FIG. 8B in which the tensile stress is induced, the warpage is reduced in almost all areas except for the center of the chip substrate. In contrast, in the case of the chip substrate of FIG. 8C in which the compressive stress is induced, the warpage is reduced in almost all areas except for the center of the chip substrate.

It may be identified through FIGS. 8A to 8C and FIG. 9 that the warpage of the chip substrate may be controlled by appropriately etching the compressive stress pattern or the tensile stress pattern of the warped chip substrate. In particular, it is identified that, when a tensile stress is induced in the chip substrate that is concavely warped based on an upper surface thereof as illustrated in FIG. 8A, the warpage may be significantly reduced. Thus, it is also identified that, through the same principle, as the compressive stress is induced in the chip substrate that is convexly warped based on the upper surface thereof, the warpage may be significantly reduced.

As a result, according to some embodiments of the present disclosure, when the warpage occurs in various types of substrates, the warpage may be reduced or prevented by selectively etching a stress control pattern having a desired shape.

The semiconductor element according to some embodiments of the present disclosure manufactured by the above-described method may be applied to various semiconductor packages.

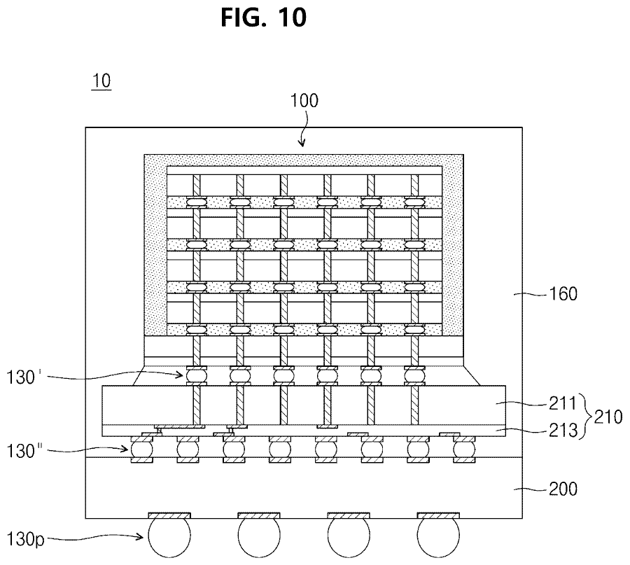

FIG. 10 illustrates a semiconductor package according to some embodiments of the present disclosure.

A semiconductor package 10 according to some embodiments of the present disclosure may include a package substrate 200, a main integrated circuit chip 210 mounted on the package substrate 200, and the semiconductor element 100 laminated on the main integrated circuit chip 210.

The semiconductor element 100 is manufactured according to the above-described embodiments, and may be, for example, the semiconductor element corresponding to FIGS. 1A and 1B or the semiconductor element corresponding to FIGS. 6A and 6B. In the following description, for convenience of description, the semiconductor element corresponding to FIGS. 6A and 6B is illustrated as an example.

The main integrated circuit chip 210 may be a processor unit. The main integrated circuit chip 210 may be, for example, a micro-processor unit (MPU) or a graphic processor unit (GPU). The main integrated circuit chip 210 may include a main chip substrate 211, a circuit layer 213, and main through-vias. Because the main through-vias have a structure similar to that of the through-vias 115 of the base chip and the integrated circuit chips, a detailed description thereof will be omitted.

Connection terminals 130′ and 130″ may be provided between the semiconductor element 100 and the main integrated circuit chip 210 and between the main integrated circuit chip 210 and the package substrate 200. The connection terminals 130′ and 130″ may include a first pad and a second pad provided to face each other and connectors provided between the first pad and the second pad. The connectors may be at least one of a conductive bump, a conductive ball, a conductive pin, a conductive lead, a conductive pillar, or a combination thereof. For example, each of the connectors may include a conductive pillar or a solder ball.

An upper surface of the package substrate 200 and upper surfaces and side surfaces of the semiconductor element 100 and the main integrated circuit chip 210 may be at least partially covered by an outer encapsulant 160.

An external connection terminal 130p may be attached to a bottom surface of the package substrate 200. The external connection terminal 130p may be attached to, for example, a lower pad. The external connection terminal 130p may be, for example, a solder ball or a bump. The external connection terminal 130p may electrically connect the semiconductor package 10 and an external device.

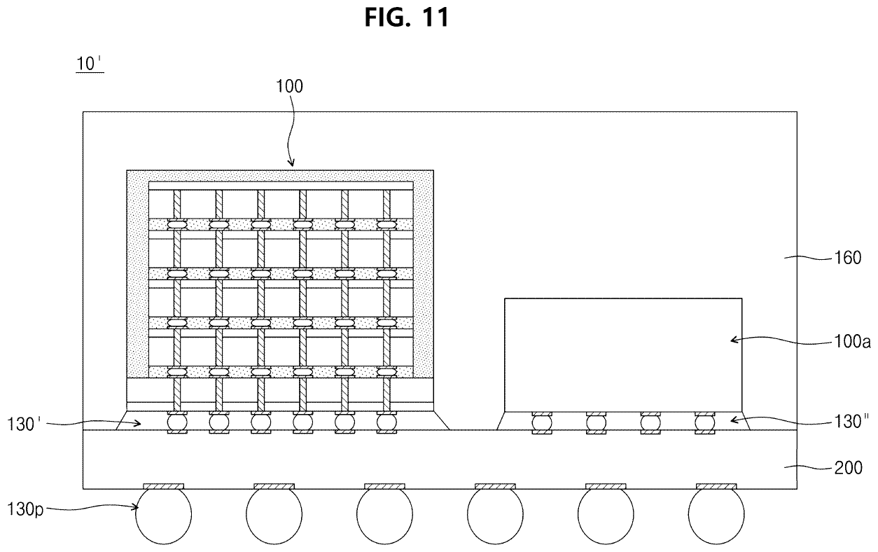

FIG. 11 illustrates a semiconductor package according to some embodiments of the present disclosure.

Referring to FIG. 11, a semiconductor package 10′ according to some embodiments of the present disclosure may include the package substrate 200, the first semiconductor element 100 mounted on the package substrate 200, and a second semiconductor element 100a.

The first semiconductor element 100 may be manufactured according to the above-described embodiments, and may be, for example, the semiconductor element corresponding to FIGS. 1A and 1B or the semiconductor element corresponding to FIGS. 6A and 6B. In the present description, for convenience of description, the semiconductor element corresponding to FIGS. 6A and 6B is illustrated as an example.

The second semiconductor element 100a may be the same as or different from the first semiconductor element 100. In some embodiments, the second semiconductor element 100a may include a high bandwidth memory (HBM), a hybrid memory cube (HMC), a double data rate fifth-generation (DDR5) DRAM, or a combination thereof. Alternatively, the second semiconductor element 100a may include a microprocessor, a logic chip, an application processor, a graphic processing unit, a buffer chip, or a combination thereof.

The upper surface of the package substrate 200 and the upper surfaces and the side surfaces of the first semiconductor element 100 and the second semiconductor element 100a may be at least partially covered by an outer encapsulant 160.

The external connection terminal 130p may be attached to the bottom surface of the package substrate 200. The external connection terminal 130p may be attached to, for example, the lower pad. The external connection terminal 130p may be, for example, a solder ball or a bump. The external connection terminal 130p may electrically connect the semiconductor package and the external device.

The semiconductor element according to some embodiments of the present disclosure may be applied to the semiconductor package as described above, but this is merely an example, and the semiconductor element may be applied to various other semiconductor elements and various other semiconductor packages.

Although the description has been made above with reference to example embodiments of the present disclosure, it may be understood that those skilled in the art or those having ordinary knowledge in the art may variously modify and change the present disclosure without departing from the spirit and technical scope of the present disclosure described in the appended claims. For example, in example embodiments of the present disclosure, the warpage of the substrate or the chip substrate in the semiconductor element including the integrated circuit chips are prevented or reduced, but the example embodiments may be applied to prevent or reduce the warpage occurring in the other used substrate in addition to the semiconductor element.

According to embodiments of the present disclosure, a semiconductor element in which warpage is prevented or reduced and a method of manufacturing a semiconductor package including the same are provided.

Accordingly, the technical scope of the present disclosure is not limited to the detailed description of the specification, but should be defined by the appended claims.

What is claimed is:

1. A method of manufacturing a semiconductor element, the method comprising:
preparing integrated circuit chips, each of the integrated circuit chips including a chip substrate having a chip area and a chip scribe lane area in which a chip stress control pattern is formed;
obtaining warpage information of each of the integrated circuit chips;
deforming at least a portion of the chip stress control pattern of each of the integrated circuit chips according to the warpage information of each of the integrated circuit chips;
laminating the integrated circuit chips on a carrier substrate with adhesive layers interposed therebetween;
curing the adhesive layers; and
removing the chip scribe lane areas from the integrated circuit chips.

2. The method of claim 1, wherein preparing the integrated circuit chips includes:
preparing a substrate having the chip areas and the scribe lane areas between the chip areas;
forming a stress control pattern inside the scribe lane area; and
cutting the substrate along a cutting line defined on the scribe lane area, and
wherein the chip stress control pattern is a portion of the stress control pattern.

3. The method of claim 1, wherein, in laminating the integrated circuit chips on the carrier substrate, a front surface of the chip substrate of each of the integrated circuit chips faces an upper surface of the carrier substrate.

4. The method of claim 1, wherein, in laminating the integrated circuit chips on the carrier substrate, a rear surface of the chip substrate of each of the integrated circuit chips faces an upper surface of the carrier substrate.

5. The method of claim 1, wherein the chip substrate has a recessed portion formed inside the chip scribe lane area, and
wherein the chip stress control pattern includes a chip tensile stress pattern provided inside a first area of the recessed portion and a chip compressive stress pattern provided inside a second area of the recessed portion.

6. The method of claim 5, wherein the chip tensile stress pattern includes a first material having a thermal expansion coefficient lower than a thermal expansion coefficient of the chip substrate, and the chip compressive stress pattern includes a second material having a thermal expansion coefficient higher than the thermal expansion coefficient of the chip substrate.

7. The method of claim 5, wherein deforming the at least a portion of the chip stress control pattern includes etching at least one of the chip tensile stress pattern and the chip compressive stress pattern such that the chip tensile stress pattern and the chip compressive stress pattern have different heights from a bottom surface of the recessed portion.

8. The method of claim 7, wherein, when the chip substrate has a concave shape with respect to a front surface of the chip substrate, the chip compressive stress pattern has a height smaller than a height of the chip tensile stress pattern, and
wherein, when the chip substrate has a convex shape with respect to the front surface of the chip substrate, the chip compressive stress pattern has a height greater than the height of the chip tensile stress pattern.

9. The method of claim 1, wherein curing the adhesive layers includes simultaneously thermally compressing the laminated adhesive layers.

10. The method of claim 1, further comprising:
removing the carrier substrate before the chip scribe lane areas are removed.

11. The method of claim 10, further comprising:
forming an encapsulant configured to encapsulate the laminated integrated circuit chips and the adhesive layers after the chip scribe lane areas are removed.

12. The method of claim 1, wherein the carrier substrate has a first area on which the integrated circuit chips are laminated and a second area surrounding the first area, and
wherein the carrier substrate includes an additional stress control pattern formed inside the second area.

13. The method of claim 12, wherein the carrier substrate has a recessed portion formed inside the second area, and
wherein the additional stress control pattern includes an additional tensile stress pattern provided inside a first area of the recessed portion and an additional compressive stress pattern provided inside a second area of the recessed portion.

14. The method of claim 13, wherein the additional tensile stress pattern includes a first material having a thermal expansion coefficient lower than a thermal expansion coefficient of the carrier substrate, and the additional compressive stress pattern includes a second material having a thermal expansion coefficient higher than the thermal expansion coefficient of the carrier substrate.

15. The method of claim 14, wherein the additional tensile stress pattern and the additional compressive stress pattern have different heights from a bottom surface of the recessed portion.

16. The method of claim 1, wherein the adhesive layers include non-conductive adhesive films, and
wherein the non-conductive adhesive films vertically overlap the chip areas of two adjacent integrated circuit chips.

17. The method of claim 1, further comprising:
preparing a base chip;
arranging the integrated circuit chips, from which the chip scribe lane areas are removed, on the base chip;
forming an encapsulant configured to encapsulate the integrated circuit chips arranged on the base chip; and
cutting the base chip and the encapsulant.

18. The method of claim 1, wherein each of the integrated circuit chips further includes:
a circuit layer provided on a front surface of the chip substrate; and
a through-via passing through the substrate and connected to the circuit layer.

19. A method of manufacturing a semiconductor element, the method comprising:
preparing a substrate including chip areas and a scribe lane area between the chip areas;
forming a stress control pattern on the scribe lane area;
preparing integrated circuit chips by cutting the substrate along a cutting line defined on the scribe lane area, each of the integrated circuit chips including one of the chip areas, a chip scribe lane area, and a chip stress control pattern;
obtaining warpage information of each of the integrated circuit chips;
deforming at least a portion of the chip stress control pattern of each of the integrated circuit chips according to the warpage information of each of the integrated circuit chips;
laminating the integrated circuit chips on a carrier substrate with non-conductive adhesive films interposed therebetween;
thermally compressing and curing the non-conductive adhesive films; and
removing the chip scribe lane areas from the integrated circuit chips.

20. A method of manufacturing a semiconductor package, the method comprising:
manufacturing a semiconductor element; and
mounting the semiconductor element on a package substrate,
wherein the manufacturing of the semiconductor element includes:
preparing integrated circuit chips, each of the integrated circuit chips including a chip substrate having a chip scribe lane area in which a chip stress control pattern is formed and a chip area;
obtaining warpage information of each of the integrated circuit chips;
deforming at least a portion of the chip stress control pattern of each of the integrated circuit chips according to the warpage information of each of the integrated circuit chips;
laminating the integrated circuit chips on a carrier substrate with adhesive layers interposed therebetween;
curing the adhesive layers; and
removing the chip scribe lane areas from the integrated circuit chips.
